(19) United States
(12) Patent Application Publication
(10) Pub. No.: US 2008/0087218 A1
(43) Pub. Date: Apr. 17, 2008

(54) Board processing apparatus and method of fabricating semiconductor apparatus

(75) Inventors: Masakazu SHIMADA, Toyama-shi (JP); Hideyuki TSUKAMOTO, Toyama-shi (JP)

Correspondence Address: OLIFF & BERRIDGE, PLC, P.O. BOX 320850, ALEXANDRIA, VA, 22320-4850, US

(73) Assignee: HITACHI KOKUSAI ELECTRIC INC., TOKYO (JP)

(21) Appl. No.: 11/905,090

(22) Filed: Sep. 27, 2007

(30) Foreign Application Priority Data
Oct. 4, 2006 (JP) 2006-272739

(51) Int. Cl. H01L 21/00; B05C 11/00

(52) U.S. Cl. 118/692; 438/5; 257/E21.001

(57) ABSTRACT

A board processing apparatus and a method of fabricating a semiconductor apparatus for reducing a pressure difference between a preparing chamber and a processing chamber and restraining a rapid flow of a gas caused by the pressure difference to thereby prevent a board from being contaminated by a particle are disclosed.

### BACKGROUND OF THE INVENTION

1. Field of the Invention

The present invention relates to a board processing apparatus and a method of fabricating a semiconductor apparatus for processing a board of a semiconductor device or the like.

2. Description of Related Art

There is known a board processing apparatus of this kind having a plurality of airtight chambers contiguous to each other of a reaction chamber (processing chamber), a load/lock chamber (preparing chamber) and the like for opening and closing intervals of the airtight chambers by closing means. For example, there is publicly known a board processing apparatus for preventing dust generation by restraining an abrupt flow of a gas caused by a pressure difference between one airtight chamber and other airtight chamber by communicating the two contiguous airtight chambers when a pressure difference between the two contiguous airtight chambers becomes equal to or lower than a predetermined value (for example, JP-A-6-177060 (Patent Reference 1)).

However, according to the background art invention, a valve provided at a connecting tube communicating a load/lock chamber and a reaction chamber is opened in order to regulate the pressure difference between the load/lock chamber and the reaction chamber, and therefore, there is a concern of bringing a particle on a side of the processing chamber into the load/lock chamber. When the particle is brought into the load/lock chamber, there is a case in which the particle is adhered onto a board before processing and after processing, and inside of the load/lock chamber needs to be cleaned in order to prevent this. However, there poses a problem that when the load/lock chamber is once installed, it is difficult to attach and detach the load/lock chamber to and from the board processing apparatus, further, enormous labor and time is consumed in a manual wiping operation and a nonuniformity is brought about in a degree of cleaning.

### SUMMARY OF THE INVENTION

It is an object of the invention to provide a board processing apparatus and a method of fabricating a semiconductor apparatus for restraining a rapid flow of a gas caused by a pressure difference between a processing chamber and a preparing chamber to thereby prevent a particle from being adhered onto a board by resolving the above-described problem.

The invention is directed to a board processing apparatus including a processing chamber for processing a board, a preparing chamber contiguous to the processing chamber, a lid member for opening and closing an interval between the processing chamber and the preparing chamber, a first exhaust line for exhausting inside of the processing chamber, a second exhaust line for exhausting inside of the preparing chamber, a first pressure detector for detecting an absolute pressure value at inside of the processing chamber, a second pressure detector for detecting an absolute pressure value at inside of the preparing chamber, a pressure difference detector for detecting a pressure difference between the processing chamber and the preparing chamber, a first pressure regulating portion for regulating a pressure at inside of the preparing chamber based on the pressure value detected by the second pressure detector such that the pressure at inside of the preparing chamber becomes a first set pressure value, a second pressure regulating portion for regulating a pressure at inside of the processing chamber based on the pressure value detected by the first pressure detector such that the pressure at inside of the processing chamber becomes a second set pressure value, and a set pressure value updating portion for updating the second set pressure value based on the pressure difference between the preparing chamber and the processing chamber detected by the pressure difference detector.

According to the invention, the second set pressure value is updated based on the pressure difference between the preparing chamber and the processing chamber detected by the pressure difference detector by the set pressure updating portion, the pressure difference between the preparing chamber and the processing chamber is reduced, and therefore, a rapid flow of a gas caused by the pressure difference is restrained to thereby enable to prevent the board from being contaminated by a particle.

### BRIEF DESCRIPTION OF THE DRAWINGS

FIG. 1 is a plane view showing a board processing apparatus according to a first embodiment of the invention.

FIG. 2 is a side view showing the board processing apparatus according to the first embodiment of the invention.

FIG. 3 shows a treatment furnace of the board processing apparatus according to the first embodiment of the invention and is a sectional view taken along a line a-a of FIG. 1.

FIG. 4 is a schematic view showing peripheral structures of a processing chamber and a load/lock chamber used in the board processing apparatus according to the first embodiment of the invention.

FIG. 5 is a block diagram showing a functional constitution of a controller used in the board processing apparatus according to the first embodiment of the invention.

FIGS. 6A to 6C show a processing until a board is carried in from the load/lock chamber to the processing chamber in the board processing apparatus according to the first embodiment of the invention, in which FIG. 6A is a schematic view showing a reduced pressure state of the load/lock chamber, FIG. 6B is a schematic view showing reduced pressure states of the processing chamber and the load/lock chamber, and FIG. 6C is a schematic view showing a state of opening a furnace port gate valve.

FIGS. 7A and 7B show a pressure at inside of the processing chamber, a pressure at inside of the load/lock chamber and a pressure difference between the load/lock chamber and the processing chamber, in which FIG. 7A is a graph for explaining Comparative Example 1, and FIG. 7B is a graph for explaining Example.

FIG. 8 is a block diagram showing a functional constitution of a controller used in a board processing apparatus according to a second embodiment of the invention.

FIG. 9 is a block diagram showing a functional constitution of a controller used in a board processing apparatus according to a third embodiment of the invention.

FIGS. 10A and 10B show the pressure at inside of the processing chamber, the pressure at inside of the load/lock chamber and the pressure difference between the load/lock chamber and the processing chamber, in which FIG. 10A is a graph for explaining Comparative Example 1, and FIG. 10B is a graph for explaining Comparative Example 2.

### DESCRIPTION OF PREFERRED EMBODIMENTS

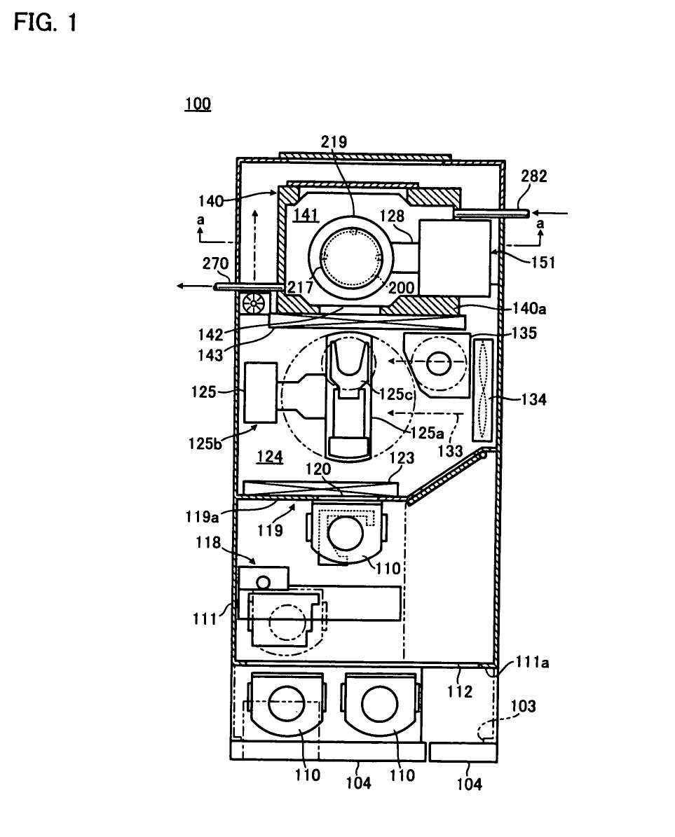

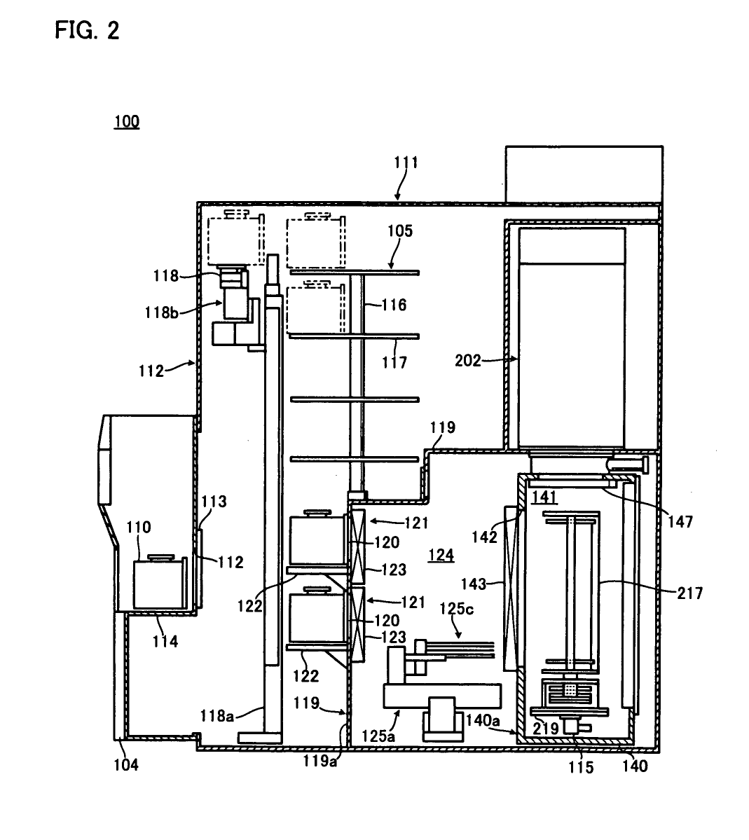

In embodiments of the invention, a board processing apparatus 100 is constituted as a semiconductor fabricating apparatus for carrying out a processing step in a method of fabricating a semiconductor apparatus (IC) as an example. Further, in the following explanation, a description will be given of a case of applying a vertical type apparatus for carrying out an oxidizing, diffusing processing, a CVD processing or the like on a board as the board processing apparatus 100 (hereinafter, simply referred to as processing apparatus). FIG. 1 is shown as a plane perspective view of the board processing apparatus 100 applied to the invention. Further, FIG. 2 is a side perspective view of the board processing apparatus 100 shown in FIG. 1.

As shown by FIGS. 1 and 2, a cabinet 111 is provided to the board processing apparatus 100 of the invention using a hoop (board container. hereinafter referred to as pod) 110 as a wafer carrier for containing a wafer (board) 200 made of silicon or the like. A front face front portion of a front wall 111a of the cabinet 111 is opened with a front face maintenance port 103 as an opening portion provided to be able to carry out maintenance, and respectively installed with front face maintenance doors 104, 104 for opening and closing the front face maintenance port 103.

The front face wall 111a of the cabinet 111 is opened with a pod carrying in/carrying out port (board container carrying in/carrying out port) 112 to communicate inside and outside of the cabinet 111, and the pod carrying in/carrying out port 112 is opened and closed by a front shutter (board container carrying in/carrying out port opening and closing mechanism) 113. A front face front side of the pod carrying in/carrying out port 112 is installed with a load boat (board container delivery base) 114, and the load boat 114 is constituted to mount to the position the pod 110 to position. The pod 110 is carried in onto the load boat 114 by an in step carrying apparatus (not illustrated) and is carried out from above the load boat 114.

A rotary type pod shelf (board container mounting shelf) 105 is installed at an upper portion substantially at a center portion in a front and rear direction of inside of the cabinet 111, the rotary type pod shelf 105 is constituted to store a plurality of pieces of the pods 110. That is, the rotary type pod shelf 105 includes a stay 116 erected vertically and rotated intermittently in a horizontal face, and a plurality of sheets of shelf plates (board container mounting base) 117 radially supported at respective positions of upper and lower four stages by the stay 116, and the plural sheets of the shelf plates 117 are constituted to be held in a state of being mounted respectively with a plurality of pieces of the pods 110.

A pod carrying apparatus (board container carrying apparatus) 118 is installed between the load boat 114 and the rotary type pod shelf 105 at inside of the cabinet 111, the pod carrying apparatus 118 is constituted by a pod elevator (board container lifting mechanism) 118a liftable while holding the pod 110 and a pod carrying mechanism (pod container carrying mechanism) 118b as a carrying mechanism, and is constituted to carry the pod 110 among load boat 114, the rotary type pod shelf 105, a pod opener (load container lid member opening/closing mechanism) 121 by a continuous operation with the pod elevator 118a and the pod carrying mechanism 118b.

A sub cabinet 119 is constructed at a lower portion of a substantially center portion in the front and rear direction of inside of the cabinet 111 over to a rear end. Pairs of wafer carrying in/carrying out ports (board carrying in/carrying out ports) 120 for carrying in and carrying out the wafer 200 to and from inside of the sub cabinet 119 are opened by being aligned to upper and lower two stages in a vertical direction at a front wall 119a of the sub cabinet 119, and the pair of pod openers 121, 121 are respectively installed at the wafer carrying in/carrying out ports 120, 120 of the upper and lower stages.

The pod openers 121 include mounting bases 122, 122 for mounting the pod 110, and cap attaching/detaching mechanisms (lid member attaching and detaching mechanism) 123, 123 for attaching and detaching a cap (lid member) of the pod 110. The pod opener 121 is constituted to open and close a wafer moving out/moving in port of the pod 110 by attaching and detaching the cap of the pod 110 mounted onto the mounting base 122 by the cap attaching/detaching mechanism 123.

The sub cabinet 119 constitutes a mounting chamber 124 fluidically isolated from spaces of installing the pod carrying apparatus 118 and the rotary type pod shelf 105. A front side region of the mounting chamber 124 is installed with a wafer mounting mechanism (board mounting mechanism) 125, and the wafer mounting mechanism 125 is constituted by a wafer mounting apparatus (board mounting apparatus) 125a capable of rotating or straightly moving the wafer 200 in the horizontal direction and a wafer mounting apparatus elevator (board mounting apparatus lifting mechanism) 125b for lifting the wafer mounting apparatus 125a. There is constructed a constitution in which by continuously operating the wafer mounting apparatus elevator 125b and the wafer mounting apparatus 125a, a tweezer (board holding member) 125c of the wafer mounting apparatus 125a charges (charging) and discharges (discharging) the wafer 200 to and from a boat (board holding piece) 217 as a mounting portion of the wafer 200.

As shown by FIG. 1, a right side end portion constituting a side opposed to a side of the wafer mounting apparatus elevator 125b of the mounting chamber 124 is installed with a clean unit 134 constituted by a supply fan and a dust preventing filter for supplying clean air 133 constituting a cleaned atmosphere or inert gas, and a notch aligning apparatus 135 constituting a board matching apparatus for matching a position in a circumferential direction of the wafer is installed between the wafer mounting apparatus 125a and the clean unit 134.

The clean air 133 blown from the clean unit 134 is constituted to flow to the notch aligning apparatus 135 and the wafer mounting apparatus 125a, thereafter, to be sucked to a duct, not illustrated, to be exhausted to outside of the cabinet 111, circulated to a primary side (supply side) constituting a sucking side of the clean unit 134 and blown to inside of the mounting chamber 124 by the clean unit 134 again.

A rear side region of the mounting chamber 124 is installed with a cabinet (hereinafter, referred to as pressure resistant cabinet) 140 having an airtight function capable of maintaining a pressure less than an atmospheric pressure (hereinafter, referred to as negative pressure), and formed with a load/lock chamber 141 constituting a preparing chamber of a load/lock type having a volume capable of containing the boat 217 by the pressure resistant cabinet 140.

A front wall 140a of the pressure resistant cabinet 140 is opened with a wafer carrying in/carrying out opening (board carrying in/carrying out opening) 142 and the wafer carrying in/carrying out opening 142 is opened and closed by a gate (board carrying in/carrying out port opening/closing mechanism) 143. A pair of side walls of the pressure resistant cabinet 140 are respectively connected with a second gas supply line 282 and a second exhaust line 270 mentioned later. An upper side of the load/lock chamber 141 is provided with a treatment furnace 202 contiguous to the load/lock chamber 141. A lower end portion of the treatment furnace 202 is constituted to be opened and closed by a furnace port gate valve (furnace port opening/closing mechanism) 147 as a lid member for opening and closing an interval between the treatment furnace 202 and the load/lock chamber 141. An upper end portion of the front wall 140a of the pressure resistant cabinet 140 is attached with a furnace port gate valve cover (not illustrated) for containing the furnace port gate valve 147 when the lower end portion of the treatment furnace 202 is opened.

As shown by FIG. 1, the pressure resistant cabinet 140 is installed with a port elevator (board holding piece lifting mechanism) 115 for lifting the boat 217. An arm 128 constituting a connecting piece connected to the port elevator 115 is horizontally installed with a seal cap 219 constituting a lid member for opening and closing an interval between the treatment furnace 202 and the load/lock chamber 141, and the seal cap 219 is constituted to be able to support the boat 217 vertically and closing the lower end portion of the treatment furnace 202. The boat 217 includes a plurality of pieces of holding members and is constituted to hold a plurality of sheets (for example, about 50 sheets through 125 sheets) of the wafers 200 respectively horizontally in a state of aligning the wafers 200 in the vertical direction by aligning centers thereof.

Next, an operation of the processing apparatus of the invention will be explained.

As shown by FIGS. 1 and 2, when the pod 110 is supplied to the load boat 114, the pod carrying in/carrying out port 112 is opened by the front shutter 113, the pod 110 above the load boat 114 is carried in from the pod carrying in/carrying out boat 112 to inside of the cabinet 111 by the pod carrying apparatus 118.

The carried in pod 110 is automatically carried by the pod carrying apparatus 118 to be delivered to the designated shelf plate 117 of the rotary type pod shelf 105, temporarily stored, thereafter, carried from the shelf plate 117 to the pod opener 121 on one side to be mounted to the mounting base 122, or directly carried to the pod opener 121 to be mounted on the mounting base 122. At this occasion, the wafer carrying in/carrying out port 120 of the pod opener 121 is closed by the cap attaching/detaching mechanism 123, the clean air 133 is made to flow to the mounting chamber 124 to be filled. For example, by filling nitrogen gas in the mounting chamber 124 as the clean air 133, an oxygen concentration is set to be far lower than an oxygen concentration of inside of the cabinet 111 (atmospheric environment) to be equal to or lower than about 20 ppm.

According to the pod 110 mounted on the mounting base 122, an opening side end face thereof is pressed to an opening edge portion of the wafer carrying in/carrying out port 120 at the front wall 119a of the sub cabinet 119, a cap thereof is detached by the cap attaching/detaching mechanism 123 and the wafer moving in/moving out port of the pod 110 is opened. Further, when the wafer carrying in/carrying out opening 142 of the load/lock chamber 141 inside of which previously brought into the atmospheric state is opened by operating the gate 143, the wafer 200 is picked up by the tweezer 125c of the wafer mounting apparatus 125a from the pod 110 by way of the wafer moving in/moving out port, the wafer is matched by the notch aligning apparatus 135, thereafter, carried in to the load/lock chamber 141 by way of the wafer carrying in/carrying out opening 142, and mounted to be charged to the boat 217 (wafer charging). The wafer mounting apparatus 125a which has delivered the wafer 200 to the boat 217 returns to the pod 110 and charges a successive one of the wafer 110 to the boat 217.

During an operation of mounting the wafer to the boat 217 by the wafer mounting apparatus 125 at the pod opener 121 of one side (upper stage or lower stage), another one of the pod 110 is carried by the pod carrying apparatus 118 from the rotary type pod shelf 105 or the load port 114 to the pod opener 121 on other side (lower stage or upper stage), and the operation of opening the pods 110 by the pod openers 121 are simultaneously progressed.

When a previously designated number of sheets of the wafers 200 are charged to the boat 217, the wafer carrying in/carrying out opening 142 is closed by the gate 143, and the pressure of the load/lock chamber 141 is reduced by being vacuumed from an exhaust tube 145. When pressures in the load/lock chamber 141 and the treatment furnace 202 are made to be the same pressure under pressure reduction by a pressure equalizing step mentioned later, the lower end portion of the treatment furnace 202 is opened by the gate valve 147. At this occasion, the furnace port gate valve 147 is carried to be contained to inside of the gate valve cover (not illustrated). Successively, the seal cap 219 is lifted by the lifting base 161 of the boat elevator 115 and the boat 217 supported by the seal cap 219 is going to be carried in (loaded) to inside of the treatment furnace 202.

After having being loaded, an arbitrary processing is carried out for the wafer 200 at the treatment furnace 202.

After having being treated, when the pressure at inside of the treatment furnace 202 and the pressure in the load/lock chamber 141 are equalized under the pressure reduction by the pressure equalizing step mentioned later, the boat 217 is extracted by the boat elevator 115. Further, the pressure at inside of the load/lock chamber 140 is recovered to the atmospheric pressure, thereafter, the gate 143 is opened. Thereafter, the wafer 200 and the pod 110 are discharged to outside of the cabinet 111 by a procedure reverse to the above-described except the wafer matching step at the notch aligning apparatus 135.

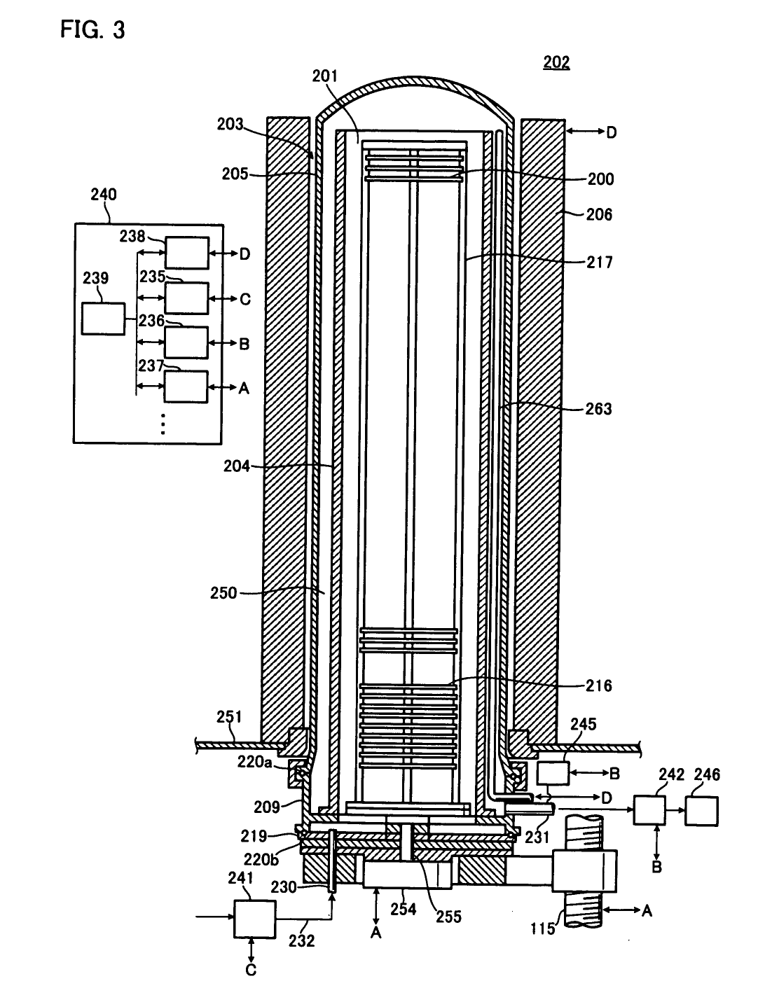

FIG. 3 is an outline constitution view of the treatment furnace 202 of the board processing apparatus 100 preferably used in the first embodiment of the invention, which is shown as a sectional view taken along a line a-a of FIG. 1.

As shown by FIG. 3, the treatment furnace 202 is provided with a heater 206 constituting a heating mechanism. The heater 206 is constituted by a cylindrical shape and is vertically installed by being supported by a heater base 251 constituting a holding plate.

An inner side of the heater 206 is arranged with a process tube 203 constituting a reaction tube in a shape of a circle concentric with the heater 206. The process tube 203 is constituted by an inner tube 204 constituting an inner reaction tube and an outer tube 205 constituting an outer reaction tube provided on an outer side thereof. The inner tube 204 made of a heat resistant material of, for example, quartz (SiO₂) or silicon carbide (SiC) or the like and is formed by a shape of a circular cylinder an upper and a lower end of which are opened. A cylindrical hollow portion of the inner tube 204 is formed with a processing chamber 201 for processing a board, and constituted to be able to contain the wafer 200 constituting the board in a state of aligning the boards in multistages in the vertical direction in a horizontal attitude by the boat 217 mentioned later. The outer tube 205 made of a heat resistant material of, for example, quartz, silicon carbide or the like, and is formed by a shape of a circular cylinder an inner diameter of which is larger than an outer diameter of the inner tube 204, an upper end of which is closed and a lower end of which is opened and is provided by a shape of a circle concentric with the inner tube 204.

A lower side of the outer tube 205 is arranged with a manifold 209 by a shape of a circle concentric with the outer tube 205. The manifold 209 made of, for example, stainless steel or the like and is formed by a shape of a circular cylinder an upper end and a lower end of which are opened. The manifold 209 is engaged with the inner tube 204 and the outer tube 205 and is provided to support these. Further, an O ring 220a is provided as a seal member between the manifold 209 and the outer tube 205. By supporting the manifold 209 by the heater base 251, the process tube 203 is brought into a state of being installed vertically. A reaction vessel is formed by the process tube 203 and the manifold 209.

A seal cap 219 mentioned later is connected with a nozzle 230 to be communicated to inside of the processing chamber 201, and the nozzle 230 is connected with a first gas supply line 232 as a gas supply part to inside of the processing chamber for supplying the gas to inside of the processing chamber 201. An upstream side constituting a side opposed to a side of being connected to the nozzle 230 of the first gas supply line 232 is connected with a processing gas supply source or an inert gas supply source, not illustrated, by way of a first MFC (mass flow controller) 241 constituting a gas flow rate controller. The first MFC 241 is electrically connected with a gas flow rate control portion (gas flow rate controller) 235 and is constituted to control a flow rate of the supplied gas to be a desired amount by a desired timing.

The manifold 209 is provided with a first exhaust line 231 for exhausting an atmosphere at inside of the processing chamber 201. The first exhaust line 231 is arranged at a lower end portion of a cylindrical space 250 formed by a gap between the inner tube 204 and the outer tube 205, and is communicated with the cylindrical space 250. A downstream side of the first exhaust line 231 constituting a side opposed to a side of being connected to the manifold 209 is connected with an exhaust pump 246 constituting an exhausting apparatus by way of a first pressure sensor 245 constituting a first pressure detector for detecting an absolute pressure value at inside of the processing chamber 201 and a pressure regulating valve 242 constituting a pressure regulating apparatus, and is constituted to be able to vacuum to exhaust such that a pressure at inside of the processing chamber 201 becomes a predetermined pressure (vacuum degree). The pressure regulating valve 242 and the first pressure sensor 245 are electrically connected with a pressure control portion (pressure controller) 236, and the pressure control portion 236 is constituted to control the pressure at inside of the processing chamber 201 to be a desired pressure at a desired timing by the pressure regulating valve 242 based on the pressure detected by the first pressure sensor 245.

A lower side of the manifold 209 is provided with the seal cap 219 constituting a furnace port lid member capable of closing and opening at a lower end of the manifold 209 in airtight. The seal cap 219 is brought into contact with a lower end of the manifold 209 from a lower side in the vertical direction. The seal cap 219 is made of a metal of, for example, stainless steel or the like and is formed by a shape of a circular disk. An upper, face of the seal cap 219 is provided with an ring 220b constituting a seal member brought into contact with a lower end of the manifold 209. A side of the seal cap 219 opposed to the processing chamber 201 is installed with a rotating mechanism 254 for rotating the boat. A rotating shaft 255 of the rotating mechanism 254 is connected to the boat 217 mentioned later by penetrating the seal cap 219 and is constituted to rotate the wafer 200 by rotating the boat 217. The seal cap 219 is constituted to be lifted in the vertical direction by the boat elevator 115 constituting the lifting mechanism vertically equipped to an outer portion of the process tube 203, thereby, the boat 217 can be carried in and carried out to and from the processing chamber 201. The rotating mechanism 254 and the boat elevator 115 are electrically connected with a drive control portion (drive controller) 237 and is constituted to be controller to carry out a desired operation at a desired timing.

The boat 217 constituting the board holding piece is made of a heat resistant material of, for example, quartz, silicon carbide or the like, and is constituted to align a plurality of sheets of the wafers 200 in a horizontal attitude and in a state of aligning centers thereof in multistages. Further, a lower portion of the boat 217 is arranged with a plurality of sheets of heat insulating plates 216 constituting heat insulating members constituted by a circular plate shape made of a heat resistant material of, for example, quartz, silicon carbide or the like in a horizontal attitude in multistages and is constituted to make heat from the heater 206 difficult to be transferred to the side of the manifold 209.

Inside of the process tube 203 is arranged with a temperature sensor 263 as a temperature detector. The heater 206 and the temperature sensor 263 are electrically connected with a temperature control portion 238 and is constituted to control a temperature at inside of the processing chamber 201 to be a desired temperature distribution at a desired timing by adjusting a degree of conducting electricity to the heater 206 based on temperature information detected by the temperature sensor 263.

The gas flow rate control portion 235, the pressure control portion 236, the drive control portion 237, the temperature control portion 238 constitute also an operating portion, an input/output portion and is electrically connected to a main control portion (main controller) 239 for controlling a total of the board processing apparatus. The gas flow rate control portion 235, the pressure control portion 236, the drive control portion 237, the temperature control portion 238, the main control portion 239 are constituted as a controller 240.

Next, an explanation will be given of a method of forming a thin film on the wafer 200 by a CVD method as one step of steps of fabricating a semiconductor device by using the treatment furnace 202 according to the above-described constitution. Further, in the following explanation, operation of respective portions constituting the board processing apparatus is controlled by the controller 240.

When a plurality of sheets of the wafers 200 are charged to the boat 217 (wafer charge), as shown by FIG. 3, the boat 217 holding the plurality of sheets of wafers 200 is lifted by the boat elevator 115 and is carried into the processing chamber 201 (boat loading). Under the state, the seal cap 219 is brought into a state of sealing a lower end of the manifold 209 by way of the O ring 220b.

Inside of the processing chamber 201 is vacuumed by the vacuuming apparatus 246 to constitute a desired pressure (vacuum degree). At this occasion, the pressure at inside of the processing chamber 201 is measured by the first pressure sensor 245, and the pressure regulating valve 242 is controlled by a feedback control based on a measured pressure. Further, inside of the processing chamber 201 is heated by the heater 206 to constitute a desired temperature. At this occasion, the degree of conducting electricity to the heater 206 is controlled by a feedback control based on temperature information detected by the temperature sensor 263 to constitute a desired temperature distribution at inside of the processing chamber 201. Successively, the wafer 200 is rotated by rotating the boat 217 by the rotating mechanism 254.

Next, a gas supplied from a processing gas supply source and controlled to constitute a desired flow rate by MFC 241 is introduced into the processing chamber 201 from the nozzle 230 by flowing in the first gas supply line 232. The introduced gas is moved up at inside of the processing chamber 201, flows from the upper end opening of the inner tube 204 into the cylindrical space 250 and is exhausted from the exhaust tube 231. When the gas passes through inside of the processing chamber 201, the gas is brought into contact with a surface of the wafer 200 and at this occasion, a thin film is deposited on the surface of the wafer 200 by a thermal CVD reaction (deposition).

When a previously set processing time period has elapsed, an inert gas is supplied from an inert gas supply source and the inert gas substitutes for inside of the processing chamber 201, and an inside of the processing chamber 201 is maintained in a reduced pressure state.

Thereafter, when the pressures of the load/lock chamber 141 and the processing chamber 201 are equalized under a reduced pressure by the pressure equalizing step, mentioned later, the seal cap 219 is moved down by the boat elevator 115, the lower end of the manifold 209 is opened, and the processed wafer 200 is carried out to outside of the process tube 203 from the lower end of the manifold 209 in a state of holding the processed wafer 200 by the boat 217 (boat unloading). Thereafter, the processed wafer 200 is taken out from the boat 217 (wafer discharge).

Further, as an example, as processing conditions when the wafer is processed by the processing furnace according to the embodiment, for example, in forming an SiN film (silicon nitride), there are exemplified a processing temperature of 400 through 800° C., a processing pressure of 1 through 50 Torr, film forming gas species of SiH₂Cl₂, NH₃, a film forming gas supply flow rate of SiH₂Cl₂:0.02 through 0.30 slm, NH₃:0.1 through 2.0 slm, further, in forming Poly-Si film (polysilicon film), there are exemplified a processing temperature of 350 through 750° C., a processing pressure of 1 through 50 Torr, forming gas species SiH₄, a film forming gas supply flow rate of 0.01 through 1.20 slm, and the wafer 200 is processed by maintaining the respective processing conditions constant at certain values in respective ranges.

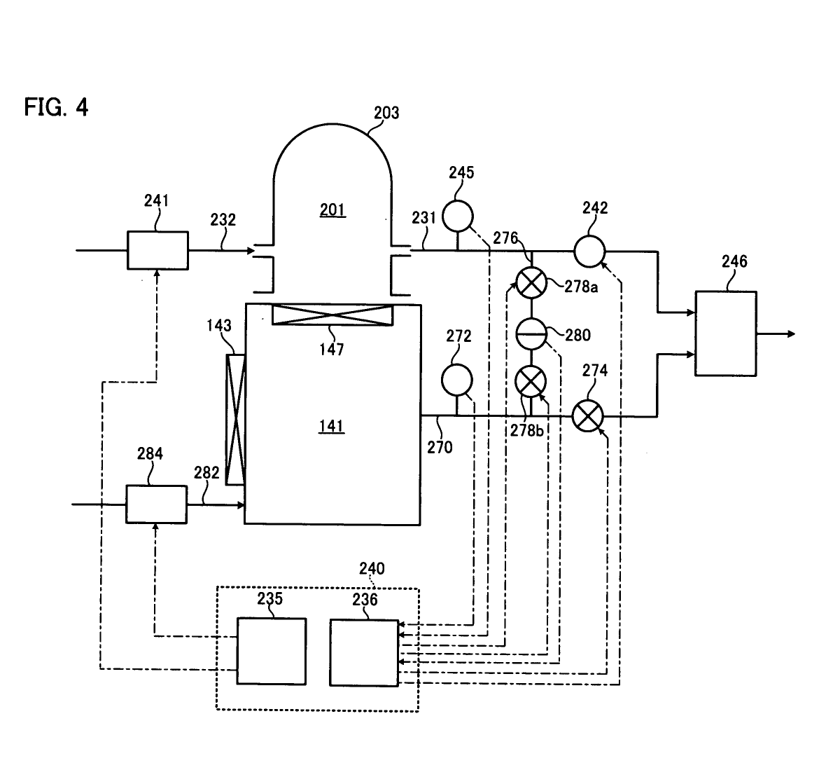

Next, a detailed description will be given of peripheral structures of the processing chamber 201 and the load/lock chamber 141 in reference to FIG. 4.

As shown by FIG. 4, the load/lock chamber 141 is provided with a second exhaust line 270 for exhausting an atmosphere at inside of the load/lock chamber 141. A second pressure sensor 272 as a second pressure detector is provided at the second exhaust line 270 and detects an absolute pressure value at inside of the load/lock chamber 141. An opening/closing valve 274 is provided at the second exhaust line 270, and is arranged on the downstream side of the second pressure sensor 272. A pressure difference detecting line 276 is connected to the first exhaust line 231 and the second exhaust line 270, and the pressure difference detecting line 276 is arranged with two air valves 278a, 278b and a pressure difference meter 280 as a pressure difference detector. The pressure difference detector 280 is arranged between two of the air valves 278a and the air valve 278b for detecting a pressure difference between the processing chamber 201 and the load/lock chamber 141. The exhaust pump 246 is connected to the first exhaust line 231 and the second exhaust line 270, and arranged on the downstream side of the pressure regulating valve 242 and the opening/closing valve 274. As described above, the interval between the processing chamber 201 and the load/lock chamber 141 is provided with the furnace port gate valve 147 constituting the lid member for opening and closing the interval between the processing chamber 201 and the load/lock chamber 141.

Further, a second gas supply line 282 constituting a portion of supplying the gas to inside of the preparing chamber is connected to the load/lock chamber 141 by way of a second MFC (mass flow controller) 284 constituting a gas flow rate controller and supplies an inert gas of nitrogen gas or the like to inside of the load/lock chamber 141.

The flow rate control portion 235 is connected to the first MFC 241 and the second MFC 284 and is constituted to control gas flow rates supplied to inside of the processing chamber 201 and inside of the load/lock chamber 141. Further, not only singles of the first MFC 241 and the second MFC 284 but also pluralities thereof may be connected thereto respectively in accordance with, for example, gas species, gas flow rates.

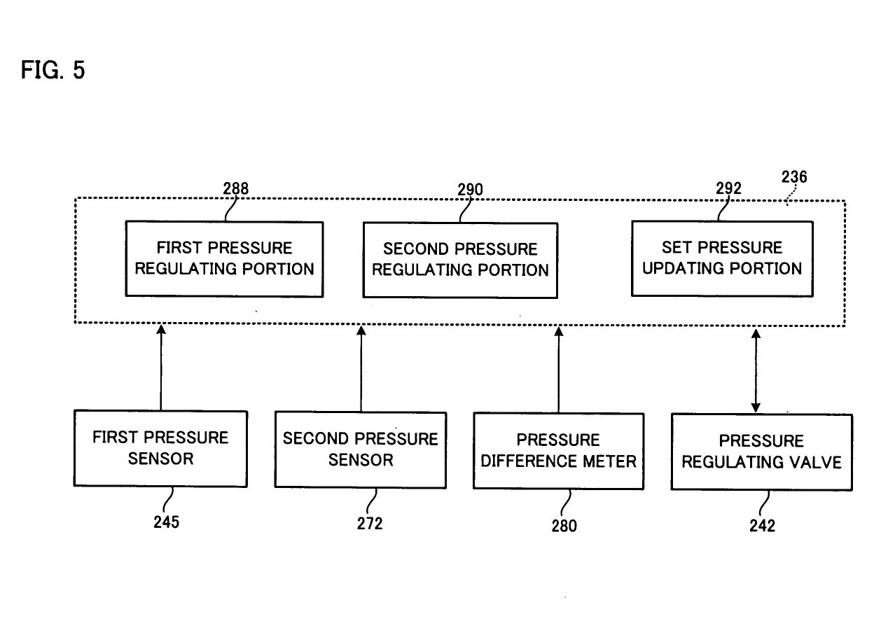

FIG. 5 shows a functional constitution of the pressure control portion 236.

The pressure control portion 236 includes a first pressure regulating portion 288, a second pressure regulating portion 290 and a set pressure updating portion 292. Further, the pressure control portion 236 is connected with the first pressure sensor 245, the second pressure sensor 272 and the pressure difference meter 280, and receives pressure values detected by the first pressure sensor 245, the second pressure sensor 272 and the pressure difference meter 280. Further, the pressure control portion 236 is connected with the pressure regulating valve 242 and the opening/closing valve 274, the air valve 278a and the air valve 278b (shown in FIG. 4) for controlling operations of the pressure regulating valve 242 and the opening/closing valve 274, the air valve 278a and the air valve 278b.

The set pressure updating portion 292 is previously stored with a predetermined set pressure value. Further specifically, the set pressure updating portion 292 is previously stored with a first set pressure value for setting a pressure value at inside of the load/lock chamber 141 and a second set pressure value for setting a pressure value at inside of the processing chamber 201. The first set pressure value and the second set pressure value are set to negative pressures (pressures less than atmospheric pressure). The second set pressure value may preferably be set to a value substantially the same as the first set pressure value. Further, both of the first set pressure value and the second set pressure value are constituted to be able to be changed arbitrarily.

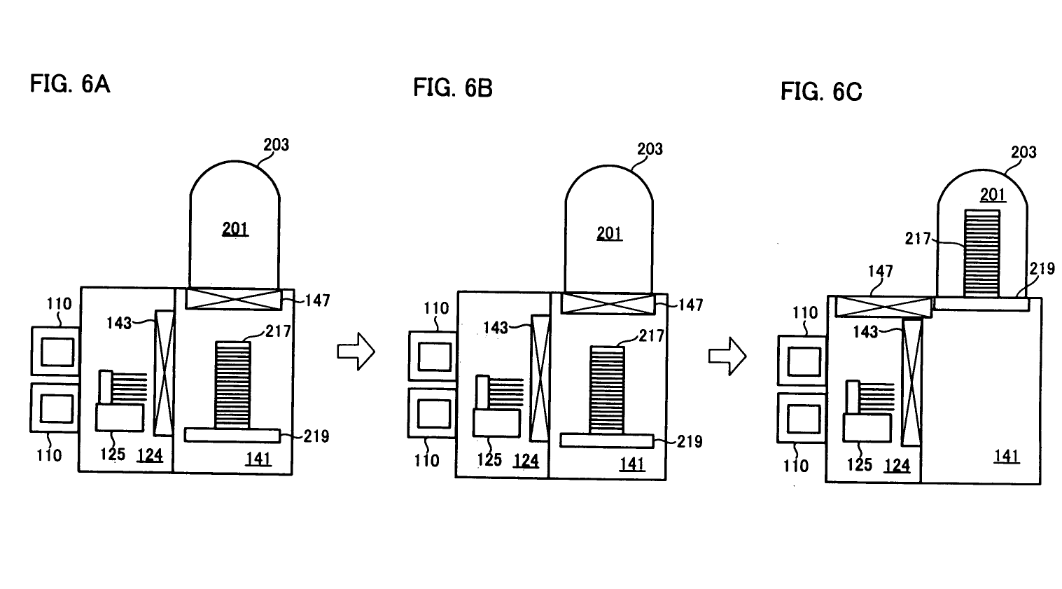

Next, an explanation will be given of a pressure equalizing step between the processing chamber 201 and the load/lock chamber 141 of the board processing apparatus 100 according to the embodiment based on FIG. 4 through FIG. 6C. As shown also by FIG. 6A, the pressure control portion 236 brings inside of the load/lock chamber 141 from the atmospheric state to the negative pressure state. Further specifically, the first pressure regulating portion 288 of the pressure control portion 236 opens the opening/closing valve 274 prior to opening the furnace port gate valve 147 and exhausts the atmosphere at inside of the load/lock chamber 141 by the exhaust pump 246 by way of the second exhaust line 270. At this occasion, the first pressure regulating portion 288 regulates the pressure at inside of the load/lock chamber 141 such that the pressure at inside of the load/lock chamber 141, that is, a pressure value detected by the second pressure sensor 272 becomes the first set pressure value previously stored at the set pressure updating portion 292. Further, at this occasion, as necessary, the pressure at inside of the load/lock chamber 141 may be regulated by regulating a flow rate of a gas supplied to the load/lock chamber 141 by controlling the second MFC 284 by way of the flow rate control portion 235 such that the pressure value detected by the second pressure sensor 272 becomes the first set pressure value previously stored to the set pressure updating portion 292. The first pressure regulating portion 288 closes the opening/closing valve 274 when the pressure value detected by the second pressure sensor 272 reaches the first set pressure value.

Also as shown in FIG. 6B, the pressure control portion 236 brings inside of the processing chamber 201 into a negative pressure state. Further specifically, the second pressure regulating portion 290 of the pressure control portion 236 operates the pressure regulating valve 242 (regulates an opening degree thereof) prior to opening the furnace port gate valve 147, and exhausts the atmosphere at inside of the processing chamber 201 by the exhaust pump 246 by way of the first exhaust line 231. At this occasion, the second pressure regulating portion 290 regulates the pressure at inside of the processing chamber 201 by regulating a flow rate of a gas exhausted from the processing chamber 201 by controlling the pressure regulating valve 242 such that the pressure at inside of the processing chamber 201, that is, a detected value of the first pressure sensor 245 becomes the second set pressure value constituting an initial value previously stored to the set pressure updating portion 292 (such that the second set pressure value is maintained). Further, at this occasion, as necessary, the second pressure regulating portion 290 may regulate the pressure at inside of the processing chamber 201 by regulating a flow rate of a gas exhausted from the processing chamber 201 and a gas flow rate of an inert gas supplied to the processing chamber 201 by controlling the pressure regulating valve 242 as well as the first MFC 241 such that the detected value of the first pressure sensor 245 becomes the second set pressure value previously stored to the set pressure updating portion 292.

Successively, prior to opening the gate value 147, when the pressure value detected by the second pressure sensor 272 becomes the first set pressure value and the pressure value detected by the first pressure sensor 245 becomes the second set pressure value, the set pressure updating portion 292 of the pressure control portion 236 opens the air valves 278a, 278b and updates the second set pressure value by adding or subtracting the pressure difference between the processing chamber 201 and the load/lock chamber 141 outputted from the pressure difference meter 280 to or from the second set pressure value stored to the set pressure updating portion 292. Successively, the second pressure regulating portion 290 regulates the pressure at inside of the processing chamber 201 such that the pressure difference between the processing chamber 201 and the load/lock chamber 141 outputted from the pressure difference meter 280 is within a predetermined range by operating the pressure regulating valve 242 based on the updated set pressure value. Preferably, the second pressure regulating portion 290 may carry out PID (Proportional Integral Differential) operation at a control period within, for example, 1 second, further update (correct) the second set pressure value updated at each predetermined time (real time) to be able to regulate the opening degree of the pressure regulating valve 242 to automatically regulate the pressure at inside of the processing chamber 201. Further, at this occasion, as necessary, the second pressure regulating portion 290 may control the first MFC 241 in addition to operating the pressure regulating valve 242 based on the updated set pressure value, regulate the flow rate of the gas exhausted from the processing chamber 201 and the gas flow rate of the inert gas supplied to the processing chamber 201 and regulate the pressure at inside of the processing chamber 201.

Thereby, the pressure difference between inside of the pressure chamber 201 and inside of the load/lock chamber 141 is reduced and the pressures at inside of the processing chamber 201 and inside of the load/lock chamber 141 can be stabilized. Further, a range of capable of being measured by the pressure difference meter 280 may previously be set and when the pressure value detected by the pressure difference meter 280 is at outside of a predetermined range, an error processing may be carried out.

Also as shown in FIG. 6C, the drive control portion 237 (shown in FIG. 3) opens the furnace port gate valve 147. Successively, the drive control portion 237 carries the boat 217 from the load/lock chamber 141 to inside of the processing chamber 201. The controller 240 processes the board (wafer 200) supported by the boat 217 at inside of the processing chamber 201.

After having been processed the board, the second pressure regulating portion 290 operates the pressure regulating valve 242 and controls the first MFC 241, supplies an inert gas to inside of the processing chamber 201 and substitutes the inert gas for inside of the processing chamber 201. After substituting the inert gas or substituting the inert gas, inside of the processing chamber 201 is maintained in the negative pressure state.

Further specifically, the second pressure regulating portion 290 of the pressure control portion 236 operates the pressure regulating valve 242 (regulates the opening) prior to opening the seal cap 219, and exhausts the atmosphere at inside of the processing chamber 201 by the exhaust pump 246 by way of the first exhaust line 231. At this occasion, the second pressure regulating portion 290 controls the pressure regulating valve 242 such that the pressure at inside of the processing chamber 201, that is, the detecting value of the first pressure sensor 245 becomes the second set pressure value constituting the initial value previously stored to the set pressure updating portion 292 (such that the second set pressure value is maintained) and regulates the pressure at inside of the pressure chamber 201. Further, at this occasion, the second pressure regulating portion 290 may regulate the pressure at inside of the processing chamber 201 by regulating the flow rate of the gas exhausted from the processing chamber 201 and the gas flow rate of the inert gas supplied to the processing chamber 201 by controlling the pressure regulating valve 242 as well as the first MFC 241 such that the detecting value of the first pressure sensor 245 becomes the second set pressure value previously stored to the set pressure updating portion 292.

Further, the second pressure regulating portion 290 of the pressure control portion 236 opens the opening/closing vale 274 prior to opening the seal cap 219 and exhausts the atmosphere at inside of the load/lock chamber 141 by the exhaust pump 246 by way of the second exhaust line 270. At this occasion, the first pressure regulating portion 288 regulates the pressure at inside of the load/lock chamber 141 such that the pressure at inside of the load/lock chamber 141, that is, the pressure value detected by the second pressure sensor 272 becomes the first set pressure value previously stored to the set pressure updating portion 292. Further, at this occasion, as necessary, the flow rate of the gas supplied to the load/lock chamber 141 may be regulated and the pressure at inside of the load/lock chamber 141 may be regulated by controlling the second MFC 284 by way of the gas flow rate control portion 235 such that the pressure value detected by the second pressure sensor 272 becomes the first set pressure value previously stored to the pressure set updating portion 292. The first pressure regulating portion 288 closes the opening/closing valve 274 when the pressure value detected by the second pressure sensor 272 reaches the first set pressure value.

Successively, prior to opening the seal cap 219, when the pressure value detected by the second pressure sensor 272 becomes the first set pressure value and the pressure value detected by the first pressure sensor 245 becomes the second set pressure value, the set pressure updating portion 292 of the pressure control portion 236 opens the air valves 278a, 278b and updates the second set pressure value by adding or subtracting the pressure difference between the processing chamber 201 and the load/lock chamber 141 outputted from the pressure difference meter 280 to and from the second set pressure value stored to the set pressure updating portion 292 by the pressure regulating valve 242. Successively, the second pressure regulating portion 290 operates the pressure regulating valve 242 based on the updated set pressure value and regulates the pressure at inside of the processing chamber 201 such that the pressure difference between the processing chamber 201 and the load/lock chamber 141 outputted from the pressure difference meter 280 is within a predetermined range.

Preferably, the pressure at inside of the processing chamber 201 may automatically be regulated by further updating the second set pressure value updated at each predetermined time to be able to regulate the opening degree of the pressure regulating valve 242 by carrying out the PID operation by the second pressure regulating portion 292 at a control period of, for example, within a second or less. Further, at this occasion, as necessary, the second pressure regulating portion 290 may regulate the pressure at inside of the processing chamber 201 by regulating the flow rate of the gas exhausted from the processing chamber 201 and the flow rate of the gas supplied to the processing chamber 201 by controlling the first MFC 241 in addition to operating the pressure regulating valve 242 based on the updated set pressure valve.

After equalizing the pressure at inside of the processing chamber 201 and the pressure at inside of the load/lock chamber 141, the drive control portion 237 carries out the boat 217 from the processing chamber 201 to the load/lock chamber 141 while opening the seal cap 219.

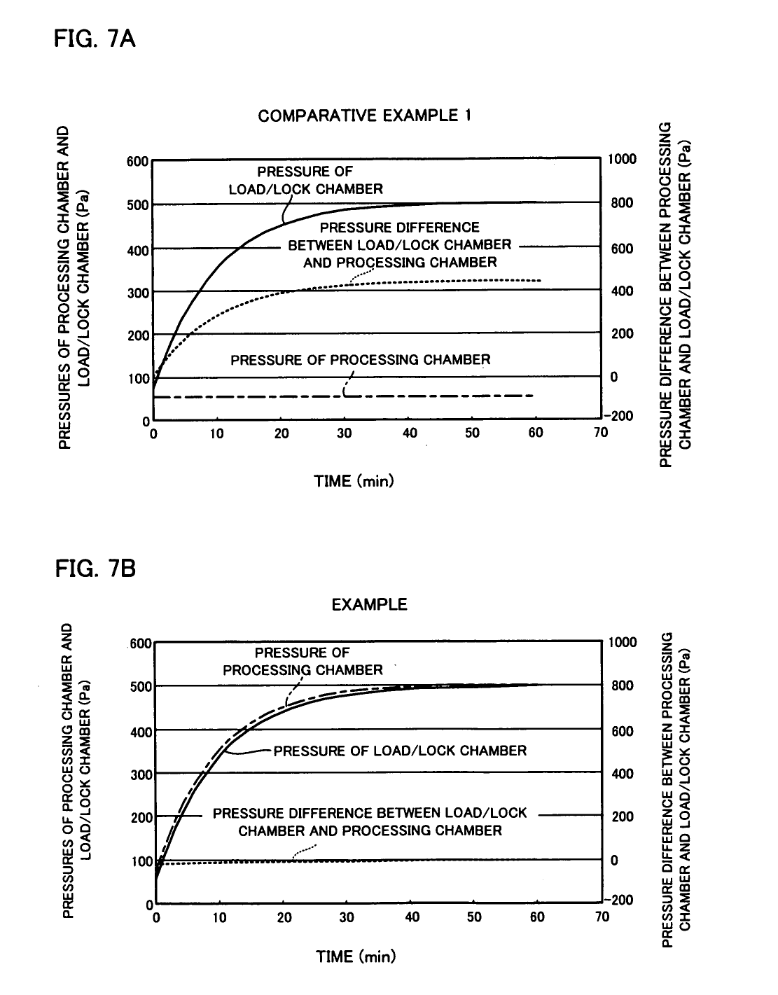

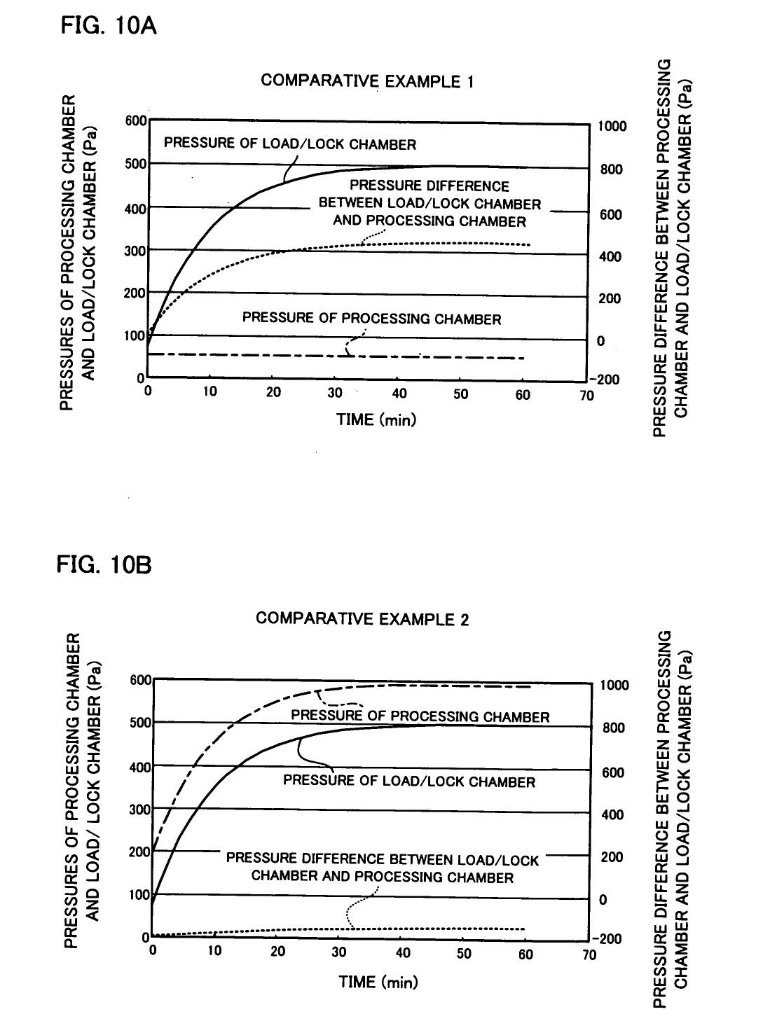

Next, comparative examples and an example will be explained in reference to FIGS. 7A and 7B and FIGS. 10A and 10B.

### Comparative Example 1

The atmospheres at inside of the processing chamber 201 and inside of the load/lock chamber 141 are exhausted to be brought into negative pressure states and changes in the pressure values at inside of the processing chamber 201 and inside of the load/lock chamber 141 are measured. As shown by FIG. 7A and FIG. 10A, the pressure value (bold line in the drawing) of inside of the load/lock chamber 141 detected by the second pressure sensor 272 rises over time by a pressure rise factor (a small amount of leakage of a seal portion of a hermetically seal portion between the gate valve 143 or the furnace port gate valve 147 and the load/lock chamber 141 or the like). The pressure value at inside of the processing chamber 201 detected by the first pressure sensor 245 (one-dotted chain line in the drawing) becomes substantially constant by operating the pressure regulating valve 242 by the second pressure regulating portion 290. The pressure difference (broken line in the drawing) between the processing chamber 201 and the load/lock chamber 141 detected by the pressure difference meter 280 rises over time.

### Comparative Example 2

The atmospheres at inside of the processing chamber 201 and inside of the load/lock chamber 141 are exhausted to be brought into negative pressure states and changes in the pressure values at inside of the processing chamber 201 and inside of the load/lock chamber 141 are measured. According to the comparative example, the pressure at inside of the processing chamber 201 is controlled based on the detected values of the first pressure sensor 245 and the second pressure sensor 272. As shown by FIG. 10B, although a relative pressure difference (broken line in the drawing) between the processing chamber 201 and the load/lock chamber 141 detected by the first pressure sensor 245 and the second pressure sensor 272 is reduced in comparison with that of Comparative Example 1, the absolute pressure difference between the processing chamber 201 and the load/lock chamber 141 (difference between bold line and one-dotted chain line in the drawing) is not reduced by a factor of an environment of use, a sensor calibrating situation or the like.

### Example

The pressure difference between the processing chamber 201 and the load/lock chamber 141 detected by the pressure difference sensor 280 is added or subtracted to or from the set pressure value on the side of the processing chamber 201 (second set pressure value), the second set pressure value is updated, and the pressure of the processing chamber 201 is regulated based on the updated set pressure value. As shown by FIG. 7B, in comparison with Comparative Examples 1 and 2, the relative pressure difference (broken line in the drawing) between the processing chamber 201 and the load/lock chamber 141 and the absolute pressure difference (difference between bold line and one-dotted chain line in the drawing) between the processing chamber 201 and the load/lock chamber 141 are reduced and the pressures of the processing chamber 201 and the load/lock chamber 141 become substantially the same.

As described above, according to the board processing apparatus 100 according to the invention, the pressure difference between the processing chamber 201 and the load/lock chamber 141 can be reduced even when a zero point of either of the first pressure sensor 245 for detecting the pressure at inside of the processing chamber 201 and the pressure sensor 272 for detecting the pressure at inside of the load/lock chamber 141 is shifted, that is, even when the pressure sensors are not calibrated, or even when the pressure at inside of the processing chamber 201 or the pressure at inside of the load/lock chamber 141 rises by the pressure rise factor. That is, by updating the set pressure value by adding or subtracting the pressure difference value detected by the pressure difference meter 280 to or from the set pressure value of the processing chamber 201 and regulating the pressure at inside of the processing chamber 201 based on the updated set pressure valve, in accordance with a pressure variation at inside of the load/lock chamber 141, the pressure at inside of the processing chamber 201 can be varied, and therefore, the pressure difference between inside of the processing chamber 201 and inside of the load/lock chamber 141 can firmly be nullified substantially (equalizing pressure). Thereby, a rapid flow of the gas caused by the pressure difference between the processing chamber 201 and the load/lock chamber 141 is restrained to thereby prevent a particle from being brought about. Further, the pressure difference between the processing chamber 201 and the load/lock chamber 141 may be constituted by a value near to zero and preferably constituted by zero. Further, even when the pressure for equalizing the pressures of the processing chamber 201 and the load/lock chamber 141 is the atmospheric pressure, the pressures can be equalized when the embodiment of the invention is applied, preferably, the embodiment may be applied to a pressure reduced case. Further preferably, the embodiment may be applied to pressure equalization under high vacuum within a range of 30 through 1200 Pa.

Further, when the pressures at inside of the processing chamber 201 and inside of the load/lock chamber 141 are equalized, the processing chamber 201 and the load/lock chamber 141 are not communicated in a state in which the pressure difference is present, and therefore, a particle can be prevented from flying up at inside of the processing chamber 201, or a particle on the side of the processing chamber 201 can be prevented from being brought into the load/lock chamber 141. That is, the board can be prevented from being contaminated by a particle.

Further, the pressure difference between inside of the processing chamber 201 and inside of the load/lock chamber 141 is regulated by updating the second set pressure value stored to the set pressure updating portion 292 by a plurality of times at each predetermined time (real time) by the pressure difference outputted from the pressure difference meter 280, and therefore, the pressure difference is reduced and accurately stabilized and reproducibility and reliability can be promoted.

Further, by the pressure difference value detected by the pressure difference meter 280, the set pressure value of the processing chamber 201 is updated, and the pressure at inside of the processing chamber 201 is regulated based on the updated set pressure value, and therefore, a control route of controlling the pressure at inside of the processing chamber 201 can be unified. For example, although in order to control the pressure regulating valve 242 directly by the pressure value detected by the pressure difference meter 280, it is necessary to provide a function of switching to select any of control route exclusive for the pressure difference meter 280, respective control routes of the pressure difference meter 280 and the first pressure sensor 245, it is not necessary to provide these, and control of the pressure can unifiedly be controlled by constituting the absolute pressure. Further, a delay in control or a variation in the pressure caused by switching the pressure control systems can be prevented from being brought about.

Further, when the pressures at inside of the processing chamber 201 and inside of the load/lock chamber 141 are equalized, the pressure is regulated on the side of the processing chamber 201 including the pressure regulating valve 242, and therefore, it is not necessary to provide an exhaust pressure regulating unit, for example, the pressure regulating valve on the side of the load/lock chamber 141. Further, the pressure regulating valve 242 used as an exhaust pressure regulating unit used in processing a board can be used as it is. Further, it is not necessary to provide a connecting tube for communicating the processing chamber 201 and the load/lock chamber 141. Further, the first exhaust line 231 and the second exhaust line 270 are arranged at the exhaust pump 246, and therefore, the single exhaust pump 246 can be used commonly therefor. Therefore, simplification of the apparatus can be realized.

Further, in equalizing the pressures at inside of the processing chamber 201 and inside of the load/lock chamber 141, when the pressure difference detected by the pressure difference meter 280 is added or subtracted to or from the second set pressure value, it may be confirmed whether the pressures at inside of the processing chamber 201 and inside of the load/lock chamber 141 are within a predetermined range. Thereby, it can be prevented that after regulating the pressure, the pressure is regulated again. That is, it can be prevented that after regulating the pressures based on the detecting values of the pressure sensor for the processing chamber and the pressure sensor for the load/lock chamber, when the value detected by the pressure difference sensor is adjusted to nullify, even in a case in which the value detected by the pressure difference sensor is nullified, the value is shifted from a pressure value scheduled to be the first pressure set value, and when the pressures values at inside of the processing chamber and at inside of the load/lock chamber are shifted from the first pressure set value to be outside of the predetermined range, it is necessary to regulate the pressure again.

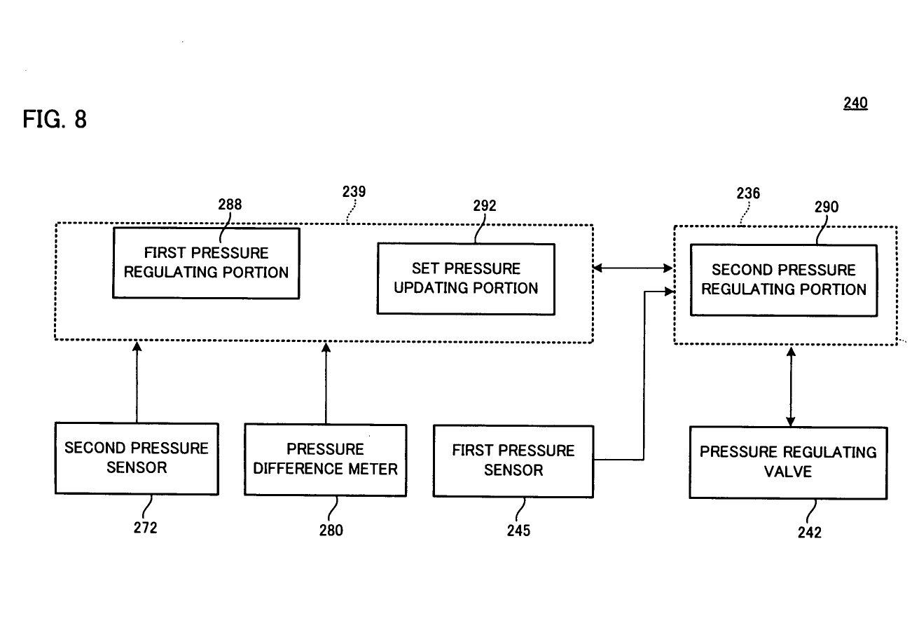

Next, a second embodiment of the invention will be explained in reference to FIG. 8.

FIG. 8 shows a functional constitution of a controller 240 according to the embodiment. The controller 240 includes a main control portion 239 and a pressure control portion 236, and the main control portion 239 is connected to the pressure control portion 236. The main control portion 239 includes the first pressure regulating portion 288 and the set pressure updating portion 292, and the main control portion 292 is connected with the second pressure sensor 272 and the pressure difference meter 278. The pressure control portion 236 includes the second pressure regulating portion 290, and the pressure control portion 236 is connected with the first pressure sensor 245 and the pressure regulating valve 242.

An operation of the controller 240 according to the embodiment will be explained.

The main control portion 239 receives the pressure difference value between the processing chamber 201 and the load/lock chamber 141 detected by the pressure difference meter 280. Successively, the main control portion 239 updates (corrects) the set pressure value by adding or subtracting the pressure difference to or from the set pressure value stored to the set pressure updating portion 292 by the set pressure updating portion 292 and transmits the updated set pressure value to the pressure control portion 236. Preferably, the main control portion 239 transmits the updated set pressure value to the pressure control portion 236 at each predetermined time (real time). The pressure control portion 236 updates the set pressure value by the second pressure regulating portion 290 at each time of transmitting the updated set pressure value from the main control portion 239 (real time) and operates the pressure regulating valve 242 based on the updated set pressure value.

Thereby, the control of regulating such that the pressure difference between the processing chamber 201 and the load/lock chamber 141 is substantially nullified is continued. Therefore, even when the pressure at inside of the load/lock chamber 141 is varied (for example, rises), the pressure difference between the processing chamber 201 and the load/lock chamber 141 is maintained to be substantially zero.

Further, in the explanation of the second embodiment according to the invention, portions the same as those of the first embodiment of the invention are attached with the same numerals in the drawing and an explanation thereof is omitted.

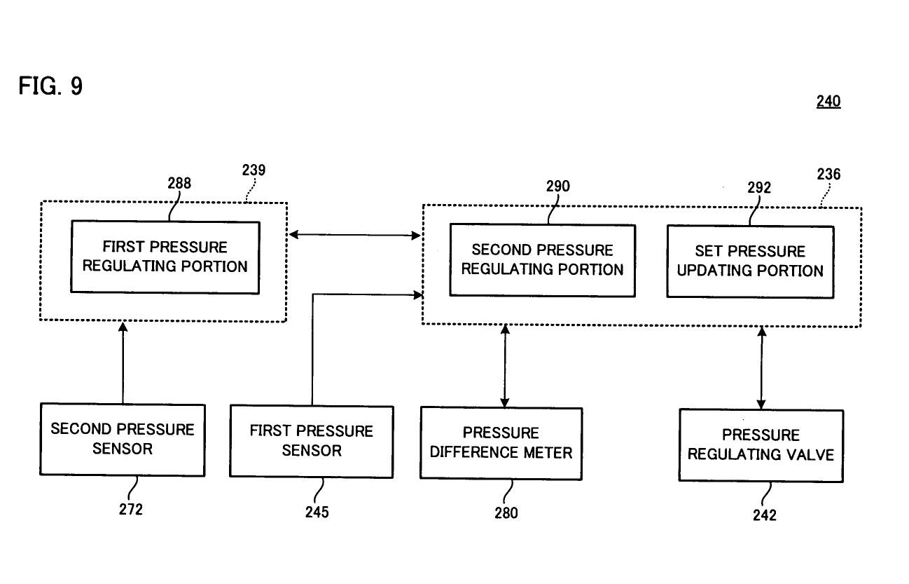

Next, a third embodiment according to the invention will be explained in reference to FIG. 9 as follows.

FIG. 9 shows a functional constitution of the controller 240 according to the embodiment. The controller 240 includes the main control portion 239 and the pressure control portion 236, and the main control portion 239 and the pressure control portion 236 are connected. The main control portion 239 includes the first pressure regulating portion 288, and the second pressure sensor 272 is connected to the main control portion 239. The pressure control portion 236 includes the second pressure regulating portion 290 and the set pressure updating portion 292, and the pressure control portion 236 is connected with the first pressure sensor 245, the pressure difference meter 280 and the pressure regulating valve 242.

An operation of the controller 240 according to the embodiment will be explained.

The pressure control portion 236 receives the pressure difference value between the processing chamber 201 and the load/lock chamber 141 detected by the pressure difference meter 280. Successively, the pressure control portion 236 updates (corrects) the set pressure value by adding or subtracting the pressure difference value to or from the set pressure value by the set pressure updating portion 292. Further, at this occasion, the pressure control portion 236 is integrally provided with the second pressure regulating portion 290 and the set pressure updating portion 292, and therefore, the control can be carried out without transmitting the pressure data or applying a load of calculating a pressure value or the like to the main control portion 239. The main control portion 239 can transmit information of switching the set pressure of a pressure control mode to the pressure control portion 236. Here, the pressure control mode information is a mode of carrying a pressure control based on any set pressure value of a plurality of set pressure values, and the set pressure switching information is information of selecting any set pressure value.

When the set pressure switching information is transmitted from the main control portion 239, the pressure control portion 236 operates the pressure regulating valve 242 based on the predetermined set pressure by the set pressure switching information. That is, the pressure control portion 236 operates the pressure control valve 242 by the second pressure regulating portion 290 based on the set pressure value updated by the set pressure updating portion 292 or the set pressure value before being updated. In this way, the pressure control mode controlled by the pressure control portion 236 may be switched based on the set pressure switching information outputted from the main control portion 239.

Further, in the explanation of the third embodiment of the invention, portions the same as those of the first embodiment of the invention are attached with the same numerals in the drawing and an explanation thereof is omitted.

The invention can be utilized in the board processing apparatus and the method of fabricating the semiconductor apparatus for processing the board of the semiconductor device or the like, which needs to prevent a particle from being brought about.

What is claimed is:

1. A board processing apparatus comprising:
a processing chamber for processing a board;
a preparing chamber contiguous to the processing chamber;
a lid member for opening and closing an interval between the processing chamber and the preparing chamber;
a first exhaust line for exhausting inside of the processing chamber;
a second exhaust line for exhausting inside of the preparing chamber;
a first pressure detector for detecting an absolute pressure value at inside of the processing chamber;
a second pressure detector for detecting an absolute pressure value at inside of the preparing chamber;
a pressure difference detector for detecting a pressure difference between the processing chamber and the preparing chamber;
a first pressure regulating portion for regulating a pressure at inside of the preparing chamber based on the pressure value detected by the second pressure detector such that the pressure at inside of the preparing chamber becomes a first set pressure value;
a second pressure regulating portion for regulating a pressure at inside of the processing chamber based on the pressure value detected by the first pressure detector such that the pressure at inside of the processing chamber becomes a second set pressure value; and
a set pressure value updating portion for updating the second set pressure value based on the pressure difference between the preparing chamber and the processing chamber detected by the pressure difference detector.

2. The board processing apparatus according to claim 1, further comprising a pressure regulating valve provided at the first exhaust line for regulating the pressure at inside of the processing chamber, an opening/closing valve provided at the second exhaust line, and an exhaust pump connected to the first exhaust line and the second exhaust line and arranged on downstream sides of the pressure regulating valve and the opening/closing valve.

3. The board processing apparatus according to claim 1, wherein prior to opening the lid member, the first pressure regulating portion exhausts the second exhaust line by the exhaust pump by opening the opening/closing valve and controls to close the opening/closing valve when the pressure value detected by the second pressure detector reaches the first set pressure value.

4. The board processing apparatus according to claim 1, wherein prior to opening the lid member, the second pressure regulating portion exhausts the first exhaust line by the exhaust pump by opening the pressure regulating valve, and controls the pressure regulating valve such that the pressure value detected by the first pressure detector is maintained at the second set pressure value.

5. The board processing apparatus according to claim 1, wherein prior to opening the lid member, when the pressure value detected by the second pressure detector becomes the first set pressure value and the pressure value detected by the first pressure detector becomes the second set pressure value, the set pressure updating portion updates the second pressure value by adding or subtracting the pressure difference detected by the pressure difference detector to or from the second set pressure value.

6. The board processing apparatus according to claim 1, wherein when the second set pressure value is updated by the set pressure updating portion, the second pressure regulating portion controls the pressure regulating valve based on the updated set pressure value.

7. The board processing apparatus according to claim 1, further comprising a portion of supplying a gas to inside of the processing chamber for supplying the gas to the processing chamber, and a portion of supplying a gas to inside of the preparing chamber for supplying the gas to the preparing chamber.

8. The board processing apparatus according to claim 1, wherein the first set pressure value and the second set pressure value are negative pressures.

9. The board processing apparatus according to claim 1, wherein the first set pressure value and the second set pressure value are substantially the same.

10. The board processing apparatus according to claim 9, wherein the second pressure regulating portion carries out a PID operation, further updates the second set pressure value updated at each predetermined time to be able to regulate an opening degree of the pressure regulating valve and regulates the pressure at inside of the processing chamber.

11. A board processing apparatus comprising:
a processing chamber for processing a board;
a preparing chamber contiguous to the processing chamber;
a lid member for opening and closing an interval between the processing chamber and the preparing chamber;
a first pressure detector for detecting an absolute pressure value of inside of the processing chamber;
a second pressure detector for detecting an absolute pressure value at inside of the preparing chamber;
a pressure difference detector for detecting a pressure difference between the processing chamber and the preparing chamber;
a first pressure regulating portion for regulating a pressure at inside of the preparing chamber based on the pressure value detected by the second pressure detector such that the pressure at inside of the preparing chamber becomes a first set pressure value;
a second pressure regulating portion for regulating a pressure at inside of the processing chamber based on the pressure value detected by the first pressure detector such that a pressure at inside of the processing chamber becomes a second set pressure value; and
a set pressure value updating portion for updating the first set pressure value based on the pressure difference between the preparing chamber and the processing chamber detected by the pressure difference detector.

12. A method of fabricating a semiconductor apparatus which is a method of fabricating a semiconductor apparatus processed by using the board processing apparatus according to claim 1, the method comprising:
a step of updating the second set pressure value based on the pressure value detected by the pressure difference detector by the pressure updating portion;
a step of opening the lid member for opening and closing the interval between the processing chamber and the preparing chamber;
a step of carrying in the board to inside of the processing chamber; and
a step of processing the board at inside of the processing chamber.

13. A method of fabricating a semiconductor apparatus which is a method of fabricating a semiconductor apparatus processed by using the board processing apparatus according to claim 11, the method comprising:
a step of updating the second set pressure value based on the pressure value detected by the pressure difference detector by the set pressure updating portion;
a step of opening the lid member for opening and closing the interval between the processing chamber and the preparing chamber;
a step of carrying in the board to inside of the processing chamber; and
a step of processing the board at inside of the processing chamber.

14. A method of fabricating a semiconductor apparatus which is a method of fabricating a semiconductor apparatus processed by using the board processing apparatus according to claim 1, the method comprising:
a step of regulating the pressure at inside of the preparing chamber by exhausting the preparing chamber from the second exhaust line based on the pressure value detected by the second pressure detector such that the pressure of the preparing chamber becomes the first set pressure value by the first pressure regulating portion;
a step of regulating the pressure at inside of the processing chamber by exhausting inside of the processing chamber from the first exhaust line based on the pressure value detected by the first pressure detector such that the pressure at inside of the processing chamber becomes the second set pressure value by the second pressure regulating portion;
a step of updating the second set pressure value based on the pressure value detected by the pressure difference detector by the set pressure updating portion;
a step of opening the lid member for opening and closing the interval between the processing chamber and the preparing chamber;
a step of carrying in the board to inside of the processing chamber; and
a step of processing the board at inside of the processing chamber.
